(19) United States
(12) Patent Application Publication
(10) Pub. No.: US 2007/0152855 A1
(43) Pub. Date: Jul. 5, 2007

(54) Digital remastering system and method

(75) Inventor: Yoshi Asahi, Fountain Valley, CA (US)

Correspondence Address: FOLEY & LARDNER, 2029 CENTURY PARK EAST, SUITE 3500, LOS ANGELES, CA, 90067, US

(73) Assignee: BBE Sound Inc.

(21) Appl. No.: 11/649,060

(22) Filed: Jan. 3, 2007

Related U.S. Application Data
(60) Provisional application No. 60/755,488, filed on Jan. 3, 2006.

(51) Int. Cl. H03M 7/00

(52) U.S. Cl. 341/61

(57) ABSTRACT

A remastering system may up-convert the sample rate of an input sampled value digital program signal (DPS), generate harmonics of the up-converted signal at the sample rate of the up-converted signal, add the harmonics to the up-converted signal, and filter the resulting signal to produce a remastered signal having enhanced content compared to the original signal. The remastering system may further include a frequency-specific time alignment corrector and equalizer that delays lower frequencies of the input signal with respect to higher frequencies of the input signal to produce an alignment of signal components that is truer to the original recorded sound. The source of the input signal may be an audio CD.

This application claims priority from Provisional patent application Ser. No. 60/755,488 filed on Jan. 3, 2006, the entirety of which is incorporated herein by reference.

### BACKGROUND OF THE INVENTION

### Field of the Invention

This invention relates to the field of audio signal reproduction and to those systems and methods relating to signal conditioning for audio reproduction and more particularly to the field of enhancing the audio quality of a digital recording.

### SUMMARY OF INVENTION

A system receives an input signal from a program source such as a CD reader. The received signal is comprised of a series of sampled values and is referred to as a sampled value digital program signal (sampled value DPS or SVPS). A sample rate up-converter then samples the sampled value DPS at a sample rate in excess of the sample rate of the sampled value DPS to produce an up-converted digital program signal (up-converted DPS or UDPS). The sample rate of the up-converter may be selected to be several times the highest frequency that the original recording was made at.

The up-converted DPS is processed through a harmonic generator that generates a stream of digital values representing odd harmonics of the samples of the up-converted DPS. The stream of digital values produced by the harmonic generator is referred to as a harmonic enhanced digital program signal (harmonic enhanced DPS or HEDPS). The harmonic enhanced DPS is summed with the up-converted DPS to form a composite digital program signal (composite DPS or CDPS).

The composite DPS is optionally processed through a digital low-pass filter to form a signal referred to as a filtered composite digital program signal (filtered composite DPS or FCDPS). The composite DPS or filtered composite DPS may be processed by a digital to analog converter to produce a signal referred to as a remastered analog program signal (remastered APS or RAPS) for delivery to an audio amplifier and speaker system. The composite DPS or filtered composite DPS may alternatively be stored in digital form in a computer readable medium as a remastered digital program signal (remastered DPS).

The system may optionally include a Frequency-Specific Time Alignment Corrector and Equalizer (FSTACE) that receives the input signal and supplies a filtered time aligned signal to the up-converter. The Frequency-Specific Time Alignment Corrector and Equalizer aligns and corrects the low-frequency band components and mid-frequency band components with respect to the high-frequency band components.

The system may optionally increase the bit-depth of the signal by using a higher bit precision than that used in making the original input signal.

The system may optionally receive the sampled value DPS from an analog to digital converter that generates sampled values from an analog program signal.

The system is preferably implemented using a digital signal processor (DSP).

### BRIEF DESCRIPTION OF THE DRAWINGS

FIG. 1a shows the frequency space available for information on a CD when information is sampled at a rate of 44.1 KHz.

FIG. 1b shows the increase in available frequency space up to 88.2 KHz when the sample rate is increased to 176.4 KHz with the bar at the left continuing to show that the information is stopped at 22.05 KHz.

FIG. 1c shows the bandwidth of a CD that is up-converted at 176.4 KHz when 0-66.15 KHz third order harmonics are added to the original 22.05 KHz CD signal for enhanced sound quality.

FIG. 2 shows the values at which samples are taken of a waveform obtained from a CD at 44.1 KHz in which the steps between samples are linearized.

FIG. 3 shows the values at which samples are taken of the waveform of FIG. 2 in which the sample rate is increased to 176.4 KHz.

FIG. 4 shows the result of adding sample values of third order harmonics of the waveform of FIG. 2 to corresponding sample values of the waveform of FIG. 3.

FIG. 5 is a functional block diagram of a first embodiment of a digital remastering system.

FIG. 6 is a functional block diagram of a second embodiment of a digital remastering system in which a frequency specific time alignment and equalizer process circuit is inserted to improve the processing of the input signal.

FIG. 7 is a functional block diagram of a frequency specific time alignment and equalizer circuit.

FIG. 8 is a schematic of an analog implementation of the frequency specific time alignment and equalizer circuit of FIG. 7.

### PREFERRED EMBODIMENTS

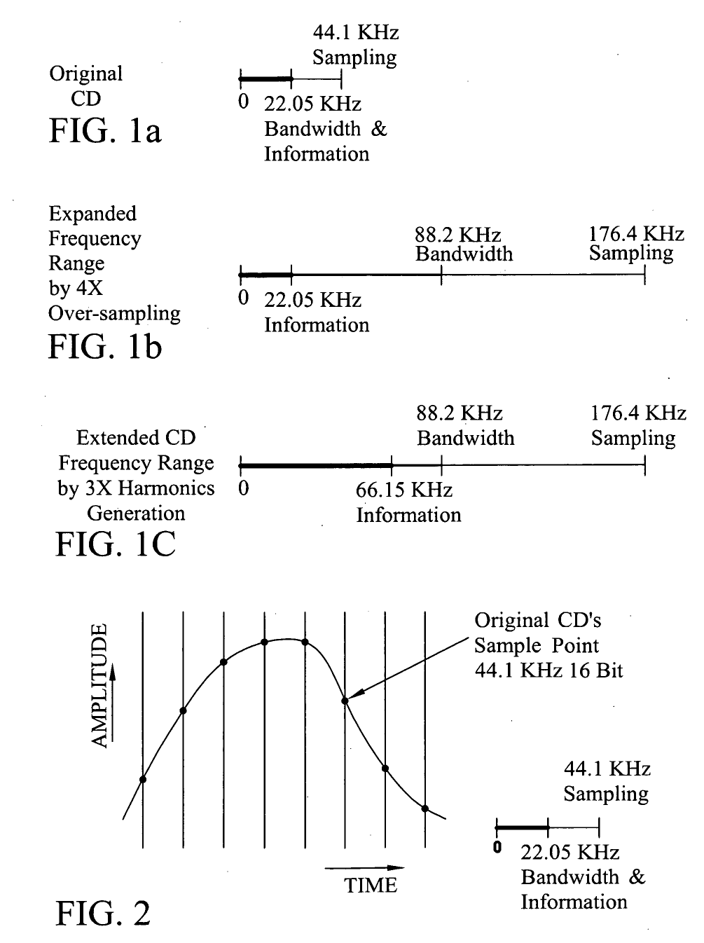

FIG. 1a shows parameters of a typical original CD that was recorded to have a bandwidth of 22.05 KHz and therefore, in accordance with the Nyquist theorem, was written at a sample rate at or in excess of 44.1 KHz. The Nyquist theorem requires that an analog signal must be sampled at a minimum of twice the rate of the highest frequency to be recovered for subsequent reconstruction. For example, if a voice frequency of 4000 Hz is to be recovered, the Nyquest theorem requires the voice signal to be sampled at least 8,000 times per second. In the case of recorded music on CDs, it is typically desired to reproduce frequencies reaching 22.05 KHz, and so the recording is made using a sample rate that is substantially equal to or higher than 44.1 KHz. A sample rate of 44.1 KHz is conventional in the CD industry.

FIG. 1b shows the effect of over-sampling of the signal of such a CD at 176.4 KHz. Over-sampling yields an expanded available bandwidth of 88.2 KHz, derived from one half of the sample rate of 176.4 KHz. However, if the audio information that was originally recorded on a master CD was recorded using conventional standards, the over-sampled data is still bandwidth limited to 22.05 KHz. Therefore sampling the information of a CD at a sample rate that is four times higher than the original sample rate does not recover information that was not previously on the disc, and there will be no difference in the sound obtained from the original CD and the over-sampled CD.

FIG. 1c shows the effect of adding harmonics produced by a third order harmonics generator to the original CD signal. The frequency range of the original CD signal is extended from 22.05 KHz as shown in FIG. 1a up to 66.15 KHz. Generating and adding such harmonics information to the signal of the original CD signal can enhance the sound quality of the original CD signal.

FIG. 2 shows a part of a waveform produced from the data on a CD. The 44.1 KHz 16 Bit sample points are shown as black dots. The horizontal and vertical axes represent time and amplitude respectively. The linear curve shows the result of low-pass-filtering of the individual sample values, as occurs when an analog signal is generated from the sample values.

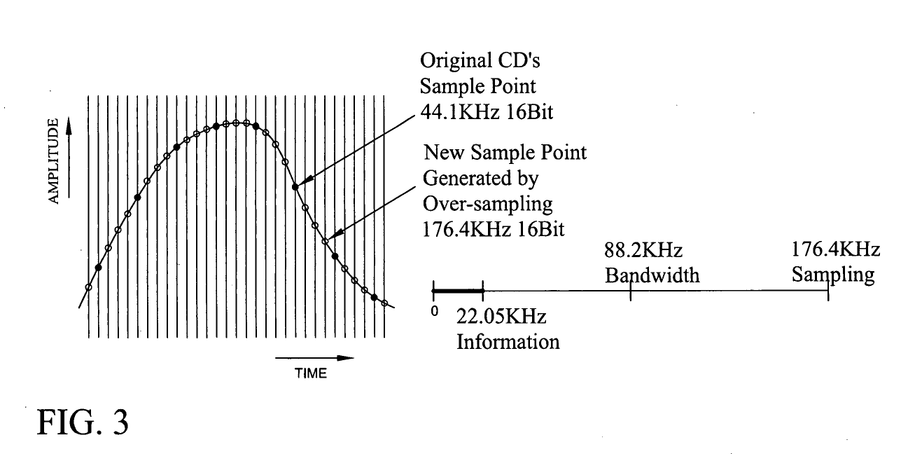

FIG. 3 shows the sample points that result when the data of FIG. 2 are over-sampled by a factor of four, in other words, at a rate of 176.4 KHz. As a result there are three sample points, shown as white dots, between each of the original sample points, shown as black dots. Over-sampling of the original CD signal at 176.4 KHz expands the bandwidth to 88.2 KHz, thereby increasing the time-resolution of the original signal, but the bandwidth of the previously recorded information remains unchanged at 22.05 KHz. The frequency space between 22.05 KHz and 88.2 KHz contains no new or added amplitude information. The newly generated sample points are generally placed or synchronized with the original expected waveform of a CD using a mathematical calculation or estimate. As a result, there is essentially no difference in the waveforms between the original CD signal and the over-sampled signal, and there is no improvement in the sound quality.

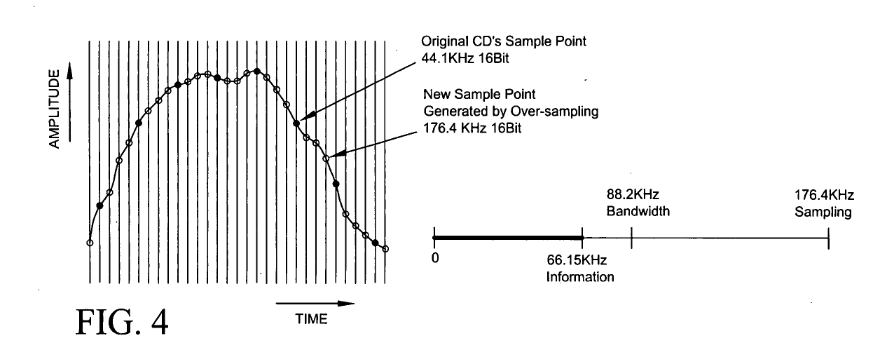

FIG. 4 shows the result of generating harmonics from the data of FIG. 2 and adding those harmonics to the data of FIG. 3. As sampling progresses with time, the harmonic information available extends from and is dependent on the frequency of the original signal at the time of sampling, the order of harmonics and the original bandwidth. When the third harmonics are added to the original signal, the information content spreads towards 3 times the highest frequency in the sample. Therefore, the highest frequency of the information extends from 22.05 KHz to 66.15 KHz.

Adding harmonics to the original over-sampled waveform naturally changes its shape. Both new sample points and original CD sample points are reallocated depending on the content of the harmonics. The new data are typically closer to the original sound than the data provided on the CD, since harmonics present in the original sound would not have been captured due to the limited 44.1 KHz sampling rate. Thus the original CD sound may be considerably changed, and when reproduced the resulting sound may appear to have been improved.

Four preferred embodiments of a Digital Remastering System for processing a signal in this manner are described. For ease of description, each embodiment is described in terms of discrete functional blocks for producing signals having defined characteristics. It is preferred that functional blocks of these embodiments are implemented using a Digital Signal Processor (DSP) that is programmed or otherwise configured to implement the functions of those functional blocks.

### First Embodiment

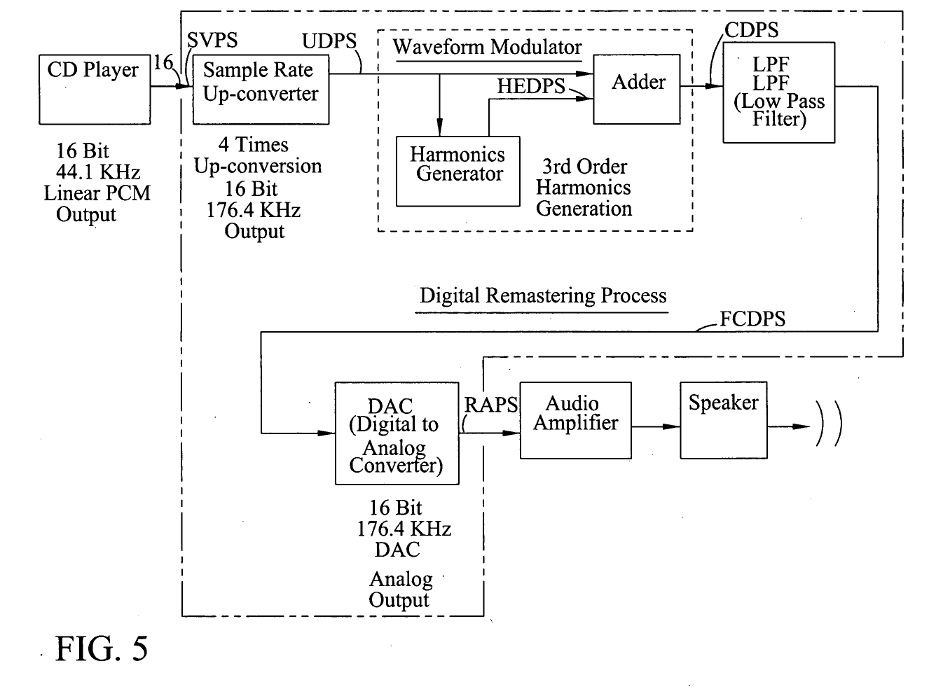

A block diagram of a first embodiment is shown in FIG. 5. In this embodiment, a CD player or reader outputs a 44.1 KHz digital signal, referred to here as a sampled value digital program signal or sampled value DPS. If the original program signal was recorded at a sample rate of 44.1 KHz using a 16 bit ADC, the sampled value DPS obtained from the CD provides 44,100 frames or values per second, each value characterizing the amplitude of the original program signal at successive increments in time, and each value having a 16 bit precision. In some instances a data precision of less than 16 bits may be used, however it is believed that this will be unusual since 16 bit formats appear to have become the de facto standard in audio systems.

In the embodiment of FIG. 5, the sampled value DPS from the CD reader is provided to an input of the Digital Remastering System. The sampled value DPS may be provided in parallel or serial format. The individual sampled values of the sampled value DPS are provided to a register (not shown) at the input of the Digital Remastering System.

The sampled value DPS received at the input of the Digital Remastering system is provided to the input of a Sample Rate Up-Converter. The Sample Rate Up-converter operates at a sample rate that is at least four times higher than the sample rate of the sampled value DPS. In a system in which the sampled value DPS signals have a sample rate of 22.05 KHz, the sample rate of the Sample Rate Up-Converter is preferably at least 174.6 KHz. The output signal of the Sample Rate Up-Converter is referred to as an up-converted DPS. The up-converted DPS is preferably provided in a serial data format.

Sample-rate up-converters are commercially available from various IC makers. For example, the Analog Devices AD1895 is an example of a 192 kHz Stereo Asynchronous Sample Rate Converter that can be configured to function as a Sample Rate Up-Converter. Analog Devices is located in Norwood, MA and convenes design seminars to familiarize designers with its products at various locations throughout the United States on a periodic schedule.

The up-converted DPS produced by the Sample Rate Up-Converter is supplied to a Waveform Modulator. Within the Waveform Modulator are a Harmonic Generator and an Adder. The up-converted DPS is supplied to both the Harmnonic Generator and to a first input of the Adder, and the output of the Harmonic Generator is supplied to a second input of the Adder. The Harmonic Generator produces a harmonic enhanced DPS or HEDP based on the up-converted DPS. For each sampled value in the up-converted DPS, the Harmonic Generator computes a corresponding value of the harmonic enhanced DPS (HEDP) using the following equation:,
HEDPSₙ₊₁=−0.5*UCDPSₙ³+1.5*UCDPS_{n,}

This computation produces a third order harmonic of the up-converted DPS. While other harmonics may also be computed and supplied to the adder, it is preferred to compute a third order harmonic since the third order harmonic is relatively easy to compute compared to even harmonics and higher order harmonics, and because the addition of third order harmonics to original program signals has been found to produce noticeable enhancement of audio quality.

The Adder receives the up-converted DPS and the harmonic enhanced DPS and sums corresponding values of those signals to generate values that form a composite DPS. Digital adders are well known in the art. As an example, the CD4038 is a CMOS triple serial adder that appears in a 1980 RCA CMOS Integrated Circuits Catalog.

The composite DPS is coupled to the input of a Low-Pass Filter (LPF) block which provides a low-pass filtering function. The LPF processes the composite DPS to produce a series of values that form a filtered composite DPS. The LPF rolls off the bandwidth of the composite DPS at a predetermined break frequency that is typically at or below 36 KHz.

The filtered composite DPS produced by the LPF may be supplied to a Digital to Analog Converter (DAC). The DAC converts the filtered composite DPS to an analog signal referred to as a remastered analog program signal. The sample rate of the DAC is higher than the sample rate of the preceding LPF. The output of the DAC may be supplied to an Audio Amplifier that provides power gain to the signal to drive a speaker load.

In an alternative arrangement, the digital values of the filtered composite DPS may be stored is a computer readable medium as a digital remastered program signal. For example, the digital remastered program signal may be stored to a hard disk drive, a volatile or non-volatile semiconductor memory device, or an optical storage medium. Audio compression processes may be performed on the digital remastered program signal before storage in the storage medium.

### Second Embodiment

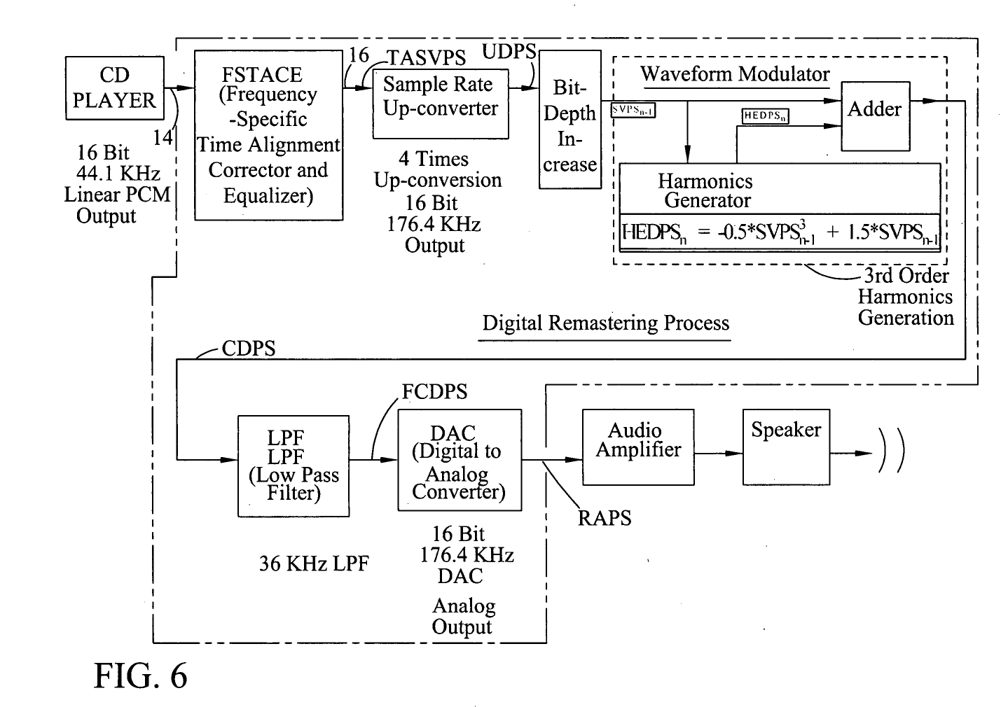

FIG. 6 shows an alternative to the embodiment of FIG. 5. In the embodiment of FIG. 6, a Frequency-Specific Time Alignment Corrector and Equalizer (FSTACE) is provided between the input of the Digital Remastering System and the Sample Rate Up-Converter, and a Bit Depth Increase block is provided between the Sample Rate Up-Converter and the Waveform Modulator.

The Frequency-Specific Time Alignment Corrector and Equalizer (FSTACE) of the embodiment of FIG. 6 receives the input sampled value DPS through an input terminal 14. The FSTACE operates as a three channel pre-amplifier having a low frequency range channel, a mid-frequency range channel and a high frequency range channel. The channels are adjusted in gain and bandwidth to obtain a predetermined Q factor (“Q”). The FSTACE also inverts the phase of the mid-frequency range channel. The effect of the Frequency-Specific Time Alignment Corrector and Equalizer is to align and correct the low-frequency band components and mid-frequency band components with respect to the high-frequency band components. The outputs of the three channels are summed to output a frequency and Q enhanced stream values that form a time aligned sample value DPS or TASVPS. The time aligned sampled value DPS is supplied to the input of the sample rate up-converter.

The Bit Depth Increase block enhances the amplitude resolution of the up-converted DPS by increasing the word length of each sample value through the addition of lower order bits to produce a bit depth increased DPS. The Harmonic Generator accordingly produces harmonic data values having the same word length as the bit depth increased DPS, and the Adder adds the bit depth increased DPS and the harmonic enhanced DPS to produce a composite signal having a greater word-length than the original sampled value DPS. The bit depth increase feature is optional, and in view of the added complexity that it introduces, need not be practiced unless increased resolution is determined to be necessary.

### Third Embodiment

In a third embodiment, the bit depth increase block of the second embodiment is eliminated.

### Fourth Embodiment

In a fourth embodiment, the sampled value DPS is supplied by a signal source that includes an analog program signal source, such as a record player or audio tape player, and an analog-to-digital converter that quantizes an analog signal from the analog program signal source and outputs sample values which are supplied as sampled value DPS to the remastering system. The analog-to-digital converter may supply sample values at a first sample rate that are then up-converted to a second sample rate as in the circuits of the first three embodiments. Alternatively, the analog-to-digital converter may supply sample values at a sample rate that does not require up-conversion. In that case, the up-converter function may be eliminated from the system of the first, second or third embodiment to which the signal is supplied.

Implementation of the Frequency Specific Time Alignment Corrector and Equalizer

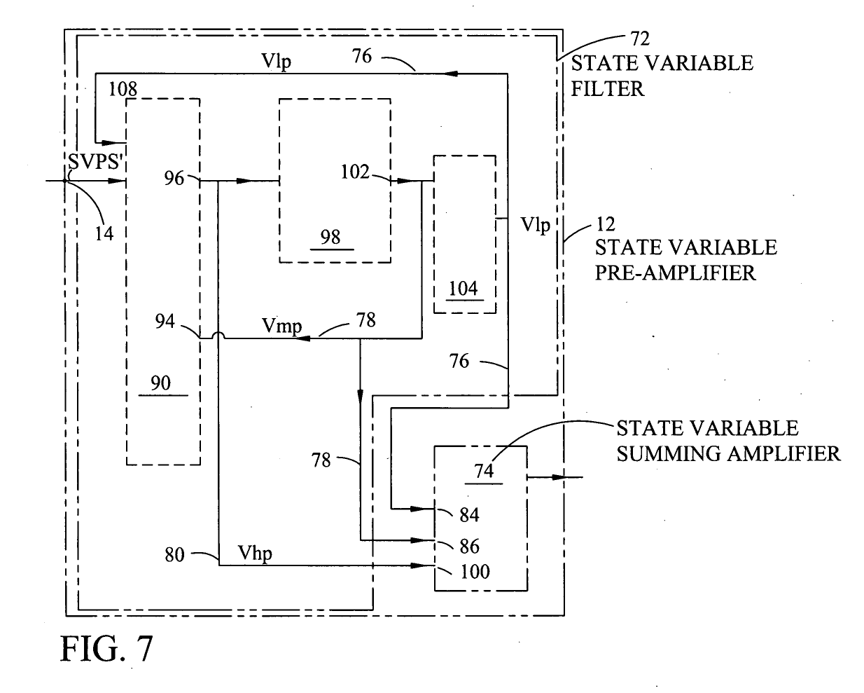

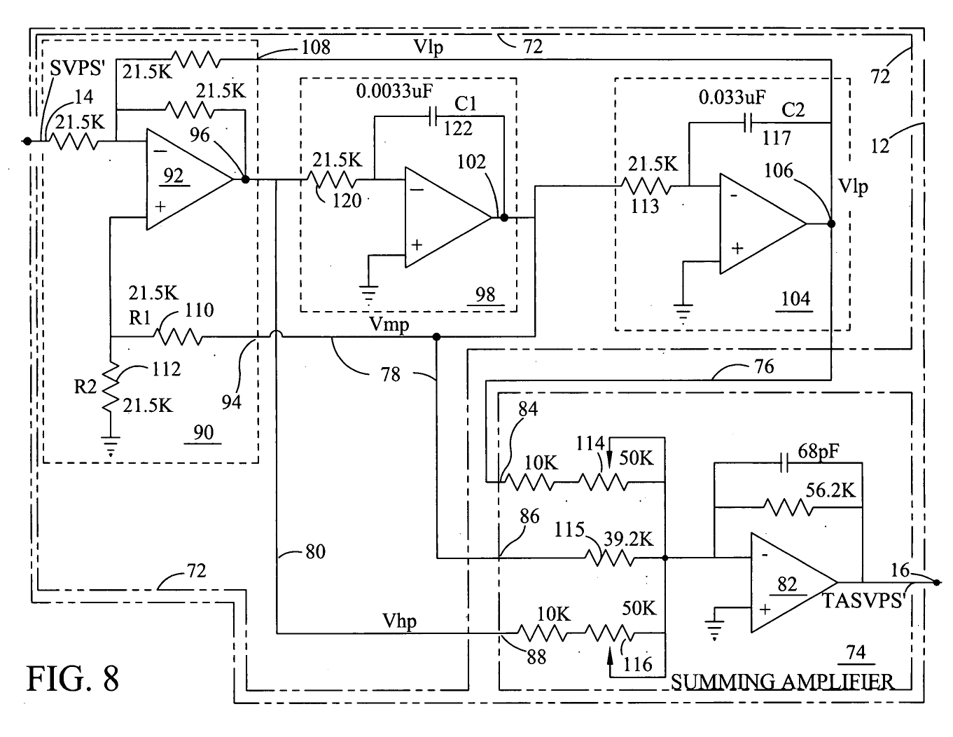

FIG. 7 shows a functional block diagram of a Frequency-Specific Time Alignment Corrector and Equalizer (FSTACE) that may be used in the embodiment of FIG. 6. FIG. 8 shows an example of an analog implementation of the circuit of FIG. 7. The circuit of FIGS. 7 and 8 is referred to as a State Variable Pre-amplifier 12. Referring to FIG. 7, the State Variable Pre-amplifier 12 is comprised of a state variable filter 72 that provides high-range, mid-range and low-range signals Vhp, Vmp and Vlp to a state variable summing amplifier 74. The state variable filter 72 preferably provides a phase shift of the mid-range signal band of approximately 180 degrees and a phase shift of the high-range signal band of approximately 360 degrees. The phase shifts of the mid-range and high-range signal bands relative to the low-range signal band effectively delays the low-range signals with respect to higher frequency signals, thus counteracting misalignment of the frequency bands produced by frequency-dependent delay effects that are encountered in signal recording and reproducing systems. In an audio frequency space having a range of 0-20,000 Hz, the state variable filter 72 preferably provides a delay of about 2.5 ms at 20 Hz with respect to the high-range components of the signal.

An analog implementation of the Frequency-Specific Time Alignment Corrector and Equalizer is now discussed with reference to FIGS. 7 and 8. In the analog implementation, the state-variable filter 72 receives a sampled value DPS′ program input signal at terminal 14. The sampled value DPS′ signal is the analog equivalent of the sampled value DPS signal in real time and is a continuous signal. The state-variable filter 72 has a first amplifier stage 90 responsive to the program signal for providing a high frequency compensated signal Vhp, a second amplifier stage 98 responsive to an output of the first amplifier stage 90 for providing a mid-range compensated signal Vmp, and a third amplifier stage 104 responsive to the mid-range compensated signal for providing a low-range compensated signal Vlp. The mid-range frequency compensated signal Vmp produced by the second amplifier stage 90 is inverted with respect to the input signal received by that stage. A state-variable summing circuit 74 adds the high frequency compensated signal, the mid-range frequency compensated signal and the low frequency compensated signal to provide a time aligned sample value DPS′ signal at terminal 16. In this example the time aligned sampled value DPS′ 16 is the analog equivalent of the time aligned sampled value DPS signal in real time and is a continuous signal. As explained in U.S. Pat. No. 6,947,567 for an Audio Boost Circuit, issued on Sep. 20, 2005, the combination of the state-variable filter 72 and the state-variable summing amplifier 74 form a functional and lower cost equivalent of the alternative embodiment three channel pre-amplifier shown in FIGS. 1 and 2 in U.S. Pat. No. 5,736,897.

Referring further to FIGS. 7 and 8, the first amplifier stage 90 is an input summing and damping amplifier circuit comprised of an amplifier 92. The input sampled value DPS′ is provided to the inverting input of the amplifier 92. A portion of the low-range frequency compensated signal Vlp produced by the third amplifier stage 104 is also provided to the inverting input of the amplifier 92 via signal line 76 and input 108. A portion of the mid-range frequency compensated signal Vmp produced by the second amplifier stage 98 is provided to the non-inverting input of the amplifier 92 through a damping circuit via signal line 78 and damping input 94. The damping circuit comprises an input resistor 110 that has its first terminal coupled to damping input 94, and its second terminal coupled to the first terminal of a resistor 112 and to the non-inverting input of the amplifier 92. The second terminal of the resistor 112 is coupled to a reference potential such as ground. The output of the amplifier 92 is the high frequency compensated signal Vhp provided at node 96, which is supplied to the high-pass input 88 of the state variable summing amplifier 74 and to the second amplifier stage 98 via signal line 80.

The second amplifier stage 98 is a mid-range band-pass amplifier that integrates the Vhp signal to provide the mid-range frequency compensated signal Vmp at node 102. The mid-range frequency compensated signal Vmp at node 102 is provided via signal line 78 to the mid-range input 86 of the state-variable summing amplifier 74 and to the damping circuit input 94 of the amplifier 92 of the first amplifier stage 90.

The third amplifier stage 104 is a low-range band-pass amplifier that integrates the Vmp signal received on signal line 78 and provides a low band-pass signal Vlp at output node 106. The low frequency compensated signal Vlp at node 106 is provided via signal line 76 to the low-pass input 84 of the state-variable summing amplifier 74 and to the input 108 of the inverting input of the amplifier 92 of the first amplifier stage 90.

The state-variable summing amplifier 74 uses an operational amplifier 82 to sum the respective Vlp, Vmp and Vhp signals received at the low-pass input 84, the mid-range input 86 and the high-pass input 88, respectively, to provide a time aligned sample value DPS′ signal at output terminal 16. The state variable summing amplifier 74 has gain control circuitry including resistors 114, 115 and 116, for balancing and summing the high, low and mid-range frequency compensated signals. The resistors may be implemented as a low frequency band-pass gain adjustment pot 114 and a high-range band-pass frequency gain adjustment pot 116 to permit a user to adjust the gain of the Vhp and Vlp signals.

The higher reactance of the smaller capacitor of the mid-range band-pass amplifier 98 sets the gain of the amplifier to higher values at lower frequencies compared to the low-range band-pass amplifier 104. The mid-range band-pass amplifier is a single pole filter. The feed back signal Vmp to the damping resistors results in a controlled Q in the mid-range frequencies band.

The ratio of the damping resistors, the gains and break frequencies of the amplifiers and integrator are set for a desired Q and band-pass. The circuit of FIG. 8 preferably has a first break frequency at approximately 240 Hz and a second at 2.24 KHz, about a decade away from the first break. The low break fc_{low} is established by the equation:
fc_{low}=½πRC2

where R and C2 are the value of resistor 113 and capacitor 117. The high frequency break fc_{High} is set by:
fc_{High}=½πRC1

where R and C1 are the value of resistor 120 and capacitor 122.

The ratio of resistors 110 and 112 establishes the Q of the state-variable filter 72. The higher the ratio of the resistors 110 and 112, the higher the Q. The Q of the state-variable filter is typically in the range of 0.5 to 2 for audio applications. The Q of the circuit of FIG. 8 is approximated by the following equation:
Q=(R₁+R₂)/3R₂ =0.67

where R1 is resistor 110 and R2 is resistor 112.

Once the Q is selected, the ratio of R1 to R2 can be calculated from the above equation. In the case of FIG. 8, a Q of 0.67 was selected based on the desired gain bandwidth response curve.

The procedure for adjusting the band-pass and gain, as proposed in the above referenced text “The Active Filter Handbook” by Frank P. Tedeschi, at pages 178-182 is to set the value of C1 and C2 to be equal and to adjust the ratio of R1 and R2 and to obtain the desired Q. In state-variable summing amplifier 74, the gain controls for the Vhp and Vlp signals provide for independent control of the gain and band-pass.

The circuit of FIG. 8 may be modeled using a computer aided analysis program such as SPICE. Break frequencies may be estimated based on information provided in referenced U.S. Pat. No. 4,638,258 issued on Jan. 20, 1987 for a Reference Load Amplifier Correction System, to Robert C. Crooks, which is incorporated herein by reference in its entirety for these teachings. Initial component values may be selected based on available components. A reactance chart may be used for a quick approximation of the required remaining value once one of the values are known. The circuit shown has a goal of a design center frequency at 700 Hz. At the center frequency, the gain of the circuit is about −1 dB or less than 1. The two adjustment pots, 114 and 116 permit an adjustment of the gain of the Vlp and the Vhp by about 15 dB with the values shown. The Q may be adjusted using the pots 114 and 116 to provide a best match to the curves in the patent to Crook. The Q and the break points may be selected to match the response characteristic of the resulting circuit to the curves in the earlier patent to yield the same phase shifts, time delays and frequency response. Resistors 114 and 116 are set for a gain of nine but a slightly higher gain of 12 is preferred.

The design of the state variable filter 72 of FIG. 8 is taught in the text “The Active Filter Handbook” by Frank P. Tedeschi, p. 178-182, Tab Books Inc. of Blue Ridge Summit, Pa., 17214. This reference does not show the outputs being summed to form the desired unbalanced output that meets the desired requirement for audio applications. The circuit of FIG. 8 is taught in commonly assigned U.S. Pat. No. 6,947,567 issued on Sep. 20, 2005.

While an analog implementation of the Frequency-Specific Time Alignment Corrector and Equalizer is presented in FIG. 8, the Frequency-Specific Time Alignment Corrector and Equalizer is preferably implemented together with other elements of the remastering system in a digital signal processor (DSP). Commercial sources are widely available for producing DSP circuits that match the functional characteristics of circuits such as those shown in FIGS. 5 and 6, and that match the performance characteristics of analog circuits such as the analog circuit of FIGS. 7 and 8. Such sources can produce an appropriate DSP based on the illustrations of FIGS. 5, 6, 7 and 8 and their corresponding descriptions. Such DSPs will typically implement all functions of those circuits except for analog-to-digital conversion for supplying sample values to the circuit input, and digital-to-analog conversion at the circuit output. The DSP may be a dedicated integrated circuit such as a microprocessor that executes instructions provided as software or firmware stored in an associated computer-readable medium, or may be implemented using a field programmable gate array. A DSP implementation of the Frequency-Specific Time Alignment Corrector and Equalizer of FIGS. 7 and 8 suitable for use in embodiments as described herein is also available is available from BBE Sound, Inc. of Huntington Beach, Calif. 92649.

While certain specific relationships, materials and other parameters have been detailed in the above description of preferred embodiments, those can be varied, where suitable, with similar results. Other applications, and variation of the present invention will occur to those skilled in the art upon reading the present disclosure. Those variations are also intended to be included within the scope of this invention as defined in the appended claims.

What is claimed is:

1. A remastering system for producing a remastered signal from a digitized audio signal, the remastering system comprising:
a sample rate up-converter for converting a received sampled value digital program signal (DPS) comprised of a series of instantaneous sampled values to an up-converted DPS signal having a higher sample rate than the sampled value DPS;
a digital adder having a first input and a second input, the first input coupled to receive the up-converted DPS;
a digital harmonic generator having an input coupled to receive the up-converted DPS and an output for providing a harmonic enhanced DPS to the second input of the digital adder,
the digital adder adding corresponding values of the up-converted DPS and the harmonic enhanced DPS to form a composite DPS; and
a digital filter having an input coupled to receive the composite DPS and providing a filtered composite DPS.

2. The remastering system of claim 1, further comprising a program signal source coupled to provide the sampled value DPS to the sample rate up-converter, the sampled value DPS comprising a series of values characterizing the amplitude of an audio signal at a periodic rate.

3. The remastering system of claim 2, wherein the program signal source is a CD reader with an output port coupled to provide a sampled value DPS comprising a series of values stored on a CD at a sample rate of the CD.

4. The remastering system of claim 2, wherein:
the program signal source provides a sampled value DPS with a sample rate that is substantially equal to or higher than 44.1 KHz, and
wherein the sample rate up-converter operates at an up-conversion sample rate that is substantially equal to or higher than 176.4 KHz.

5. The remastering system of claim 1, wherein the sample rate up-converter operates at a sample rate that is at least four times the sample rate of the sampled value DPS.

6. The remastering system of claim 1, wherein the digital harmonic generator computes a value of the harmonic enhanced DPS (HEDPS) for each value of the up-converted DPS (UCDPS) according to the equation:
HEDPSₙ₊₁=−0.5*UCDPSₙ³+1.5*UCDPSₙ

7. The remastering system of claim 1, wherein the digital filter rolls off the bandwidth of the composite DPS at a predetermined break frequency, the output sample rate of the digital filter being lower than the sample rate of the composite DPS.

8. The remastering system of claim 1, further comprising a digital to analog converter coupled to receive the filtered composite DPS and producing a remastered analog program signal.

9. A remastering system for producing a remastered signal from a digitized audio signal, the remastering system comprising:
a frequency-specific time alignment corrector and equalizer for receiving a sampled value digital program signal (DPS) comprised of a series of instantaneous sampled values, and processing low frequency range, mid-frequency range and high frequency range channels of the program signal DPS, the channels being adjusted in gain and phase and summed to output a time aligned and equalized DPS;
a sample rate up-converter for converting the time aligned and equalized DPS to an up-converted DPS signal having a higher sample rate than the time aligned DPS;
a digital adder having a first input and a second input, the first input coupled to receive the up-converted DPS;
a digital harmonic generator having an input coupled to receive the up-converted DPS and an output for providing a harmonic enhanced DPS to the digital adder second input,
the digital adder adding corresponding values of the up-converted DPS and the harmonic enhanced DPS to form a composite DPS; and
a digital filter having an input coupled to receive the composite DPS and providing a filtered composite DPS.

10. The remastering system of claim 9, further comprising a program signal source coupled to provide the sampled value DPS to the frequency-specific time alignment corrector and equalizer, the sampled value DPS comprising a series of values characterizing the amplitude of an audio signal at a periodic rate.

11. The remastering system of claim 10, wherein the program signal source is a CD reader with an output port coupled to provide a sampled value DPS comprising a series of values stored on a CD at a sample rate of the CD.

12. The remastering system of claim 10, wherein:
the program signal source provides a sampled value DPS with a sample rate that is substantially equal to or higher than 44.1 KHz, and
wherein the sample rate up-converter operates at an up-conversion sample rate that is substantially equal to or higher than 176.4 KHz.

13. The remastering system of claim 9, wherein the sample rate up-converter operates at a sample rate that is at least four times the sample rate of the sampled value DPS.

14. The remastering system of claim 9 wherein the digital harmonic generator computes a value of the harmonic enhanced DPS (HEDPS) for each value of the up-converted DPS (UCDPS) according to the equation:
HEDPSₙ₊₁=−0.5*UCDPSₙ³+1.5*UCDPSₙ

15. The remastering system of claim 9, wherein the digital filter rolls off the bandwidth of the composite DPS at a predetermined break frequency, the output sample rate of the digital filter being lower than the sample rate of the composite DPS.

16. The remastering system of claim 9, further comprising a digital to analog converter coupled to receive the filtered composite DPS and producing a remastered analog program signal.

17. A digital signal processor comprising:
a microprocessor; and
a computer readable medium storing instructions to be executed by the microprocessor, the instructions when executed by the microprocessor causing the microprocessor to perform signal processing comprising:
generating values of a harmonic of a signal from values of the signal;
adding the values of the harmonic of the signal to values of the signal to produce
values of a composite signal; and
filtering the values of the composite signal to produce values of a filtered composite signal.

18. The digital signal processor of claim 17, wherein execution of the instructions causes the microprocessor to perform further signal processing comprising:
up-converting the sample rate of values of a received digital signal to produce values of an up-converted signal,
wherein the values of a harmonic of a signal are generated from the values of the up-converted signal, and the values of the harmonic of the up-converted signal are added to corresponding values of the up-converted signal to produce values of the composite signal.

19. The digital signal processor of claim 17, wherein execution of the instructions causes the microprocessor to perform further signal processing comprising:
processing values of a received digital signal to adjust the gain and phase of low frequency range, mid-frequency range and high frequency range channels of the digital signal and sum the gain and phase adjusted channels to produce values of a time aligned and equalized signal,
wherein the values of a harmonic of a signal are generated from values of the time aligned and equalized signal, and the values of the harmonic of the time aligned and equalized signal are added to corresponding values of the time aligned and equalized signal to produce values of the composite signal.

20. The digital signal processor of claim 17, wherein execution of the instructions causes the microprocessor to perform further signal processing comprising:
processing values of a received digital signal to adjust the gain and phase of low frequency range, mid-frequency range and high frequency range channels of the digital signal and sum the gain and phase adjusted channels to produce values of a time aligned and equalized signal; and
up-converting the sample rate of values of the time aligned and equalized signal to produce values of an up-converted time aligned and equalized signal,
wherein the values of a harmonic of a signal are generated from values of the up-converted time aligned and equalized signal, and the values of the harmonic of the time aligned and equalized signal are added to corresponding values of the up-converted time aligned and equalized signal to produce values of the composite signal.

21. The digital signal processor of claim 17, wherein execution of the instructions causes the microprocessor to perform further signal processing comprising:
processing values of a received digital signal to adjust the gain and phase of low frequency range, mid-frequency range and high frequency range channels of the digital signal and sum the gain and phase adjusted channels to produce values of a time aligned and equalized signal;
increasing the word length of each value of the time aligned and equalized signal to produce values of a bit depth increased time aligned and equalized signal; and
up-converting the sample rate of values of the bit depth increased time aligned and equalized signal to produce values of an up-converted bit depth increased time aligned and equalized signal,
wherein the values of a harmonic of a signal are generated from values of the up-converted bit depth increased time aligned and equalized signal, and the values of the harmonic of the up-converted bit depth increased time aligned and equalized signal are added to corresponding values of the up-converted bit depth increased time aligned and equalized signal to produce values of the composite signal.
